(19) United States
(12) Patent Application Publication
(10) Pub. No.: US 2025/0377703 A1
(43) Pub. Date: Dec. 11, 2025

(54) POWER MANAGEMENT BASED ON PRELIMINARY SYNDROME CALCULATION

(71) Applicant: Micron Technology, Inc., Boise, ID (US)

(72) Inventors: Leon Zlotnik, Camion, CA (US); Eyal En Gad, Highland, CA (US)

(21) Appl. No.: 19/231,702

(22) Filed: Jun. 9, 2025

Related U.S. Application Data
(60) Provisional application No. 63/658,558, filed on Jun. 11, 2024.

(51) Int. Cl. G06F 1/26; H03M 13/11

(52) U.S. Cl. CPC G06F 1/26; H03M 13/1105

(57) ABSTRACT

One or more syndromes can be preliminarily calculated utilizing at least a portion of a codeword and a portion of parity-check matrix can be calculated. These preliminarily calculated syndromes can be utilized for power adjustment associated with decoding the codeword at decoders that calculate syndromes utilizing the parity-check matrix.

### PRIORITY INFORMATION

This application claims the benefit of U.S. Provisional Application No. 63/658,558, filed on Jun. 11, 2024, the contents of which are incorporated herein by reference.

### TECHNICAL FIELD

Embodiments of the disclosure relate generally to electronic systems and, in particular, to electronic systems that perform power management based on preliminary syndrome calculations.

### BACKGROUND

Various types of electronic devices such as logic circuits may store and process data. A logic circuit is an electronic circuit that processes digital signals or binary information, which can take on two possible values (usually represented as 0 and 1). The logic circuit can use logic gates to manipulate and transform the signals or binary information. Digital logic circuits can be used in a wide range of electronic devices including, for example, computers, calculators, digital clocks, and many other electronic devices that employ digital processing. Digital logic circuits can be designed to perform specific logical operations on digital inputs to generate digital outputs, and, in some instances, can be combined to form more complex circuits to perform more complex operations.

### BRIEF DESCRIPTION OF THE DRAWINGS

The present disclosure will be understood more fully from the detailed description given below and from the accompanying drawings of various embodiments of the disclosure.

FIG. 1 illustrates an example electronic system that includes a host, a controller, and a device for power management in accordance with some embodiments of the present disclosure.

FIG. 2A illustrates an example power management system in accordance with some embodiments of the present disclosure.

FIG. 2B illustrates another example power management system in accordance with some embodiments of the present disclosure.

FIG. 3 is a block diagram that illustrates an example decoding process that utilizes a preliminary syndrome calculation circuitry in accordance with some embodiments of the present disclosure.

FIG. 4 illustrates an example sparse parity-check matrix in accordance with some embodiments of the present disclosure.

FIG. 5 is a flow diagram corresponding to a method for power management based on preliminary syndrome calculation in accordance with some embodiments of the present disclosure.

FIG. 6 is a block diagram of an example computer system in which embodiments of the present disclosure may operate.

### DETAILED DESCRIPTION

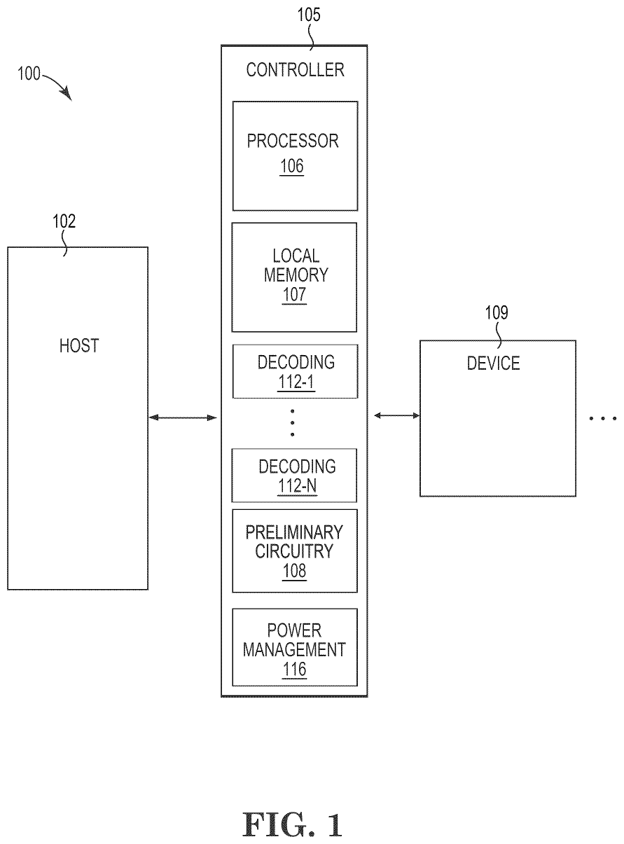

Aspects of the present disclosure are directed to electronic systems that perform power management (e.g., adjustment) based on preliminary syndrome calculations. Example electronic systems, or portions thereof, in which embodiments of the present disclosure can operate include, but are not limited to a computing system, a system-on-chip (SoC), a networking system, a communication system, a memory system (e.g., a storage system, a memory module, etc.), an artificial intelligence (AI) system, and a digital entertainment system, among various other types of systems or combinations thereof. Examples of electronic systems are described below in conjunction with FIG. 1.

Data can be written to and stored by one or more digital logic circuits and/or memory systems. The data (e.g., one or more codewords that can correspond to, for example, user data) can be encoded prior to being transferred to the memory device(s) and/or prior to being written to (e.g., stored) by the memory device(s). Upon retrieval of the data, the data is generally decoded. There are many techniques for decoding of codewords, some non-limiting examples of which include maximum likelihood decoding, minimum distance decoding (e.g., decoding techniques that seek to minimize a Hamming distance associated with a codeword), list decoding, linear decoding, bit-flip decoding, and/or information set decoding, among others.

As will be appreciated such decoding techniques can be combined with error correction techniques that can be employed to correct and/or detect bit errors in data (e.g., codewords) based on determining that bits associated with the data have incorrect states (e.g., a “1” where a “0” should be and vice versa). Some of the more common error correction techniques employed include Hamming codes, Reed-Solomon (RS) codes, Bose-Chaudhuri-Hochquenghem (BCH) codes, circular redundancy check (CRC) codes, Golay codes, Reed-Muller codes, Goppa codes, neighbor-cell assisted error correction codes, low-density parity check (LDPC) error correction codes, Denniston codes, and syndrome decoding, among others. While each of these error correction techniques enjoy their own benefits, they also can experience various drawbacks. For example, more accurate error correction techniques tend to consume more power and/or time, while less accurate error correction techniques may be performed faster and may consume less power. In the interest of clarity, the present disclosure will be described in terms of linear codes, such as LDPC codes and/or syndrome decoding, which may be generally referred to herein as “error correction techniques” or “decoding techniques,” given the context of the disclosure; however, it will be appreciated that the techniques described herein apply to other decoding techniques as well.

Some approaches may utilize multiple decoders that are tailored to achieve different objectives and/or characteristics. For example, such approaches may firstly utilize a first decoder tailored to a high efficiency type of LDPC and/or syndrome decoding and may subsequently transition to a second decoder tailored to a high reliability type of LDPC and/or syndrome decoding when needed. While powers sufficient to operate these decoders tailored to different objectives may be different. For example, operation of a decoder tailored to an efficiency characteristic may require less power consumption than operation of a decoder tailored to a reliability characteristic. However, in some approaches, the same power may be supplied in decoding data regardless of what decoder is being operated, which can be inefficient in terms of power consumption, heat generation, etc. associated with operating the decoders.

In order to address these and other deficiencies of current approaches, embodiments of the present disclosure provide a power adjustment scheme. This scheme involves dynamically adjusting various parameters, such as a voltage, a clock frequency, etc. associated with decoding data based on the desired power, performance, etc. for selectively operating decoders tailored to different objectives. For example, when the decoder tailored to reliability and/or performance characteristics is desired/selected to operate, the clock frequency, the voltage, etc. supporting its operation may be maintained at a predetermined level or increased to meet performance requirements or decreased to meet the power consumption requirements. Alternatively, when the decoder tailored to an efficiency characteristic is desired/selected to operate, the clock frequency, the voltage supporting its operation may be decreased to mitigate unnecessary power consumption that would occur when operating the decoder tailored to reliability and/or performance.

In some embodiments, the power adjustment can be preemptively determined based on an indication provided from circuitry that can preliminarily perform a syndrome calculation (alternatively referred to as “preliminary syndrome calculation) prior to further routing (e.g., transferring) the data to the decoders that perform “full” syndrome calculations. For example, the preliminary syndrome calculation can be utilized as indication of which one of decoders has sufficient capability of correcting errors on and/or decoding the data. The preliminary syndrome calculation (alternatively referred to as “preliminary syndrome calculation circuitry”) operates in a much-simplified manner compared to the “full” syndrome calculations and/or decoding operations. As described further herein, the preliminary syndrome calculation can be performed utilizing a particular portion of the codeword and/or the parity-check matrix that demonstrates a strong correlation with the overall bit error rate (BER) of the entire codeword (which would generally be indicated by the full syndrome calculation). This allows the preliminary syndrome calculation to take less time and/or less power than the “full” syndrome calculations, which reduces the latencies associated with adjusting power to operate the selected one of the decoders. Therefore, the potential cost of performing the preliminary syndrome calculation would not undermine such benefits.

FIG. 1 illustrates an example electronic system 100 that includes a host 102, a controller 105, and a device 109 for preliminary syndrome calculation in accordance with various embodiments of the present disclosure.

The electronic system 100 can be, or can be part of, for example, a desktop computer, laptop computer, televisions, home theater system, gaming console, digital camera, network router and/or switch, printer, scanner, medical device, GPS navigation device, home device (e.g., thermostat, doorbell camera, security camera, smart lock, etc.), wearable device, industrial control system (e.g., automated industrial and/or control device) mobile computing device, a vehicle (e.g., airplane, drone, train, automobile, or other conveyance), Internet of Things (IoT) enabled device, embedded computer (e.g., one included in a vehicle, industrial equipment, or a networked commercial device), system-on-chip (SoC), chipset (e.g., a collection of integrated circuits), tile, Field-Programmable Gate Array (FPGA) structure (e.g., segmented FPGA structure), or other such device.

The electronic system 100 can be, or can include, a computing fabric. As used herein, the term “computing fabric” generally refers to a conveying, multiplexing, network, computing, or communication topology in which components pass data to each other through interconnecting switches, hubs, routers, multiplexers, buses, transmission lines and rings, cables, optical couplers and fibers, electromagnetic devices, or various other means. For example, a “computing fabric” can include various components (e.g., interconnects, crossbars, networks on chip, token rings, etc.) within a computing, memory, data storage and/or processing, network and/or telecommunication, artificial intelligence, control and/or telemetry, digital entertainment and/or other system, that facilitates in-chip and/or inter-chip communication.

The electronic system 100 includes a host 102. The host 102 can include a processor chipset and a software stack executed by the processor chipset. For example, the host 102 can be, or can include, a central processing unit (CPU) or a CPU complex that can be configured to execute an operating system.

The host 102 can be coupled to the controller 105 via a physical and/or logical host interface that operates based on various communication protocols and to provide control, address, data, and other signals to the controller 105 (e.g., to further cause the controller 105 to control the device 109). Examples of the interface between the host 102 and the controller 105 can include, but not limited to, a bus interface (e.g., a serial advanced technology attachment (SATA) interface, a Serial Attached SCSI (SAS) interface, a Serial Attached SCSI (SAS) interface, a Small Computer System Interface (SCSI), a peripheral component interconnect express (PCIe) interface, ISA, etc.), a memory interface (e.g., a double data rate (DDR) interface, a dual in-line memory module (DIMM) interface, an Open NAND Flash Interface (ONFI) interface, an NVM Express (NVMe) interface), a Fibre Channel, an UART interface, an I2C interface, a Serial Peripheral Interface (SPI), an Universal Serial Bus (USB) interface, an ethernet interface, a general-purpose input/output (GIPO) interface, a custom interface, etc.

The controller 105 is communicatively coupled to one or more electronic devices 109 such that signaling can be exchanged therebetween. Non-limiting examples of the devices 109 can include microcontrollers, microprocessors, digital logic circuits, analog circuits, light emitting diodes (LEDs), displays, sensors, motors, actuators, audio amplifiers, radio frequency (RF) circuits, test and measurement instruments (e.g., oscilloscopes, multimeters, etc.), automotive electronics, medical devices, telecommunication equipment, memory devices (e.g., volatile and/or non-volatile memory devices), graphics processing units, processors/co-processors, logic blocks, intellectual property (IP) cores, etc. As used herein, a “core” or “IP core” generally refers to one or more blocks of data and/or logic that form constituent components of an application-specific integrated circuit or field-programmable gate array. The circuit portion areas can be designed, built, and/or otherwise configured to perform specific tasks and/or functions within the systems described herein.

As shown in FIG. 1, the controller 105 can include a processing device (e.g., processor 106) that can execute instructions stored in a local memory 107 to perform various operations described herein. The controller 105 can include various special purpose circuitry in the form of an ASIC, FPGA, state machine, and/or other logic circuitry that can perform operations described herein. As an example, the controller 105 can be a memory controller.

In various embodiments, one or more constituent components (e.g., host 102, controller 105, device 109, etc.) of system 100 can be part of a SoC. In one example, a device 109 itself can correspond to an SoC, while the host 102 and the controller 105 are considered “external” to the SoC. In another example, the host 102 or the controller 105, or both, can be considered as a part of an SoC along with the device 109 being internal or external to the SoC.

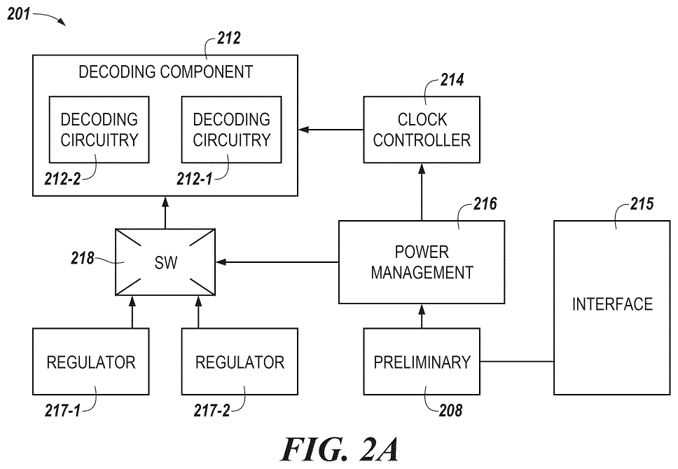

As shown in FIG. 1, the controller 105 can include preliminary syndrome calculation circuitry 108 (alternatively referred to as “preliminary circuitry” or “simply as “circuitry”), a decoding component 112 (shown as “decoding” in FIG. 1), and a power management component 116 (shown as “power management” in FIG. 1). Although not shown in FIG. 1 so as to not obfuscate the drawings, the preliminary syndrome calculation circuitry 108, the decoding component 112, and/or the power management component 116 can include various circuitry to facilitate aspects of the disclosure further described herein in FIGS. 2-5. In some embodiments, the preliminary syndrome calculation circuitry 108, the decoding component 112, and/or the power management component 116 can respectively include special purpose circuitry in the form of an ASIC, FPGA, state machine, hardware processing device, and/or other logic circuitry that can allow the preliminary syndrome calculation circuitry 108, the decoding component 112, and/or the power management component 116 to orchestrate and/or perform the operations described herein and in accordance with the disclosure. Although not illustrated in FIG. 1, the decoding component 112 can include multiple decoding circuitries (decoding circuitries 212-1, 212-2 illustrated in FIG. 2 and alternatively referred to as “decoders”) that are tailored to different objectives, such as, reliability, performance, efficiency characteristics, etc.

In some embodiments, the controller 105 includes at least a portion of the preliminary syndrome calculation circuitry 108, the decoding component 112, and/or the power management component 116. For example, the controller 105 can include a processor 106 (processing device) configured to execute instructions stored in local memory 107 for performing the operations described herein. In some embodiments, the preliminary syndrome calculation circuitry 108, the decoding component 112, and/or the power management component 116 are part of the host system 102, an application, or an operating system. The preliminary syndrome calculation circuitry 108, the decoding component 112, and/or the power management component 116 can be resident on the controller 105. As used herein, the term “resident on” refers to something that is physically located on a particular component. For example, the preliminary syndrome calculation circuitry 108, the decoding component 112, and/or the power management component 116 being “resident on” the controller 105 refers to a condition in which the hardware circuitry that comprises the preliminary syndrome calculation circuitry 108, the decoding component 112, and/or the power management component 116 are physically located on the controller 105. The term “resident on” may be used interchangeably with other terms such as “deployed on” or “located on,” herein.

FIG. 2A illustrates an example power management system 201 in accordance with some embodiments of the present disclosure. The preliminary syndrome calculation circuitry 208, the decoding component 212, and the power management component 216 illustrated in FIG. 2A can be analogous to the preliminary syndrome calculation circuitry 108, the decoding component 112, the power management component 116 illustrated in FIG. 1, respectively. Although embodiments are not so limited, the interface 215 can be an ONFI interface that operates according to the ONFI protocol. Although embodiments are not so limited, the interface 215 can also include a buffer, in which data (e.g., corresponding to a codeword) can be temporarily stored prior to being transferred further (e.g., to the decoding component 212). Although embodiments are not so limited, the power management system 201 illustrated in FIG. 2A can be a dynamic voltage and frequency scaling (DVFS) system.

In some embodiments, the clock controller 214 can be configured to adjust/alter the frequency of the clocking signals by decreasing or increasing the frequency of the clocking signals according to the gradient frequency alteration. As used herein, the frequency of clocking signals can be referred to as the “clock frequency” or “clock speed”. The clock frequency is a parameter in digital systems and electronics. The clock frequency can represent the rate at which a clock signal alternates between its high and low states (or transitions between 1 and 0) within a specific time interval. Clocking signals can be utilized to synchronize various components and operations within a digital circuit, ensuring that actions occur at precise and coordinated times. Clock frequency can be measured in hertz (Hz) and represents the number of clock cycles that occur per second. A higher clock frequency generally indicates faster processing capabilities and more rapid data transfer within a digital system. Also, the relatively higher clock frequency is also associated with higher power consumption than that of the relatively lower clock frequency. In an example illustrated in FIG. 2A, the clock signals can be provided to, at least, the decoding component 212.

The power management system 201 can include voltage regulators 217-1 and 217-2 (collectively referred to as regulators 217). As used herein, the voltage regulators can be also simply referred to as “regulators”. Although two regulators are illustrated in FIG. 2A, embodiments are not limited to a particular quantity of regulators the power management system 201 can include. The regulators 217-1 and 217-2 can be electrical power sources for the operation of the decoding component 212 (e.g., the decoding circuitries 212-1, 212-2, which are alternatively referred to as “decoders”) operates. For example, the decoding component 212 can operate based on a regulated voltage provided by the decoding circuitry 212-1 or the decoding circuitry 212-2. In some embodiments, the regulator 217-1 or the regulator 217-2, or both, can be a low dropout regulator (LDO), alternating current (AC)/direct current (DC) converter, DC/DC Buck converter, switching capacitance, etc., although embodiments are not so limited. For example, the regulator 217-1 can be an LDO, while the regulator 271-2 can be a DC/DC converter, although embodiments are not so limited.

The power management system 201 further includes a switch 218 (alternatively referred to as “switching circuitry” and shown as “SW” in FIG. 2A) coupled between the decoding component 212 and the regulators 217. The switch 218 can selectively allow one regulator 217 to provide a power supply to the decoding component 212, while another regulator may be in a reduced power state (e.g., inactive state, in which the regulator 217 is not actively providing a power supply).

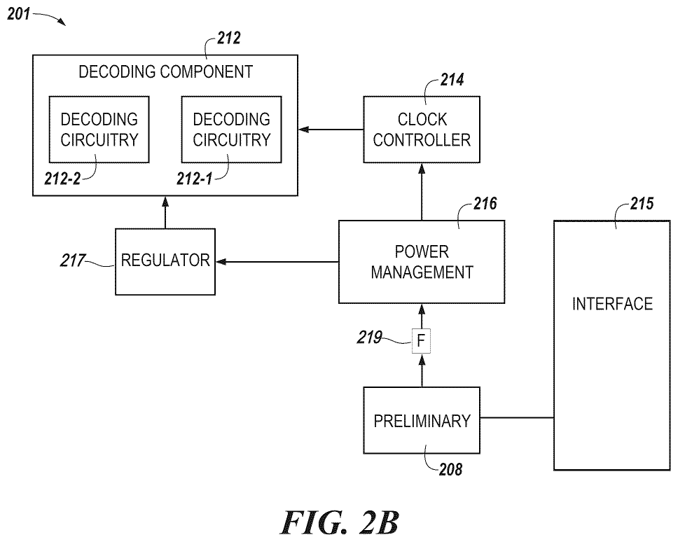

The preliminary syndrome calculation circuitry 208 (simply referred to as “preliminary circuitry”) can calculate a preliminary syndrome, which can be utilized to select one of the decoders of the decoding component 212 (e.g., decoders 212-1, 212-2) to decode data received via the interface 215. As further described in connection with FIG. 3, whether to select the decoder 212-1 or the decoder 212-2 can be determined based on a comparison of a syndrome weight of the preliminary syndrome to one or more thresholds. Embodiments are not limited to a particular quantity of decoders the decoding component 212 can include.

Although embodiments are not so limited, the decoder 212-1 can be a decoding circuitry tailored to an efficiency characteristic, while the decoder 212-2 can be a decoding circuitry tailored to a reliability characteristic. The decoder 212-1 that is tailored to an efficiency characteristic may utilize less resources than the decoder 212-2 tailored to a performance and/or reliability characteristic, while the decoder 212-2 may be capable of correcting errors on the bit strings with a BER exceeding the capability of the decoder 212-1. Accordingly, the operation of the decoder 212-2 may demand a higher clock frequency and/or a higher voltage supply than the operation of the decoder 212-1 demands.

The power management component 216 can further control the clock controller 214 to adjust a clock frequency and/or the switch 218 to adjust a voltage being provided (e.g., from the voltage regulators 217) to the decoding component 212. This adjustment can be made based on the result of the preliminary syndrome calculation (e.g., a syndrome weight of the preliminary syndrome) provided from the preliminary circuitry 208. Although embodiments are not so limited, the syndrome weight can be indicative of which one of the decoding circuitries 212 would offer a more efficient decoding of a codeword. The efficiency can be determined based on a time that would be taken for the decoding and/or a power that would be consumed by each decoder when decoding the codeword. More particularly, the efficiency can be determined based on a quantity of iterations that may be necessary to decode the codeword at the decoding circuitries 212, and/or a particular value of a clock frequency and/or a voltage (e.g., from the regulators 217) required for decoding the codeword.

For example, consider a scenario, in which the syndrome weight indicates that decoding the data requires the decoder 212 tailored to a reliability and/or performance characteristic, involves a relatively high number of iterations during the decoding process, and/or demands a high clock frequency and/or a high voltage supply. In this example, the power management component 216 can control (e.g., provide signaling to) the clock controller 214 to increase the frequency of the clock signals provided to the decoding component 212. Further, continuing with this example, the power management component 216 can control (e.g., provide signaling to) the switch 218 to selectively enable one of the regulators 217 (e.g., DC/DC converter) that is configured to provide a power supply of a high voltage (e.g., higher than that of a different regulator 217, such as an LDO). The increased clock frequency, voltage, etc. can allow fulfillment of various operational requirements for the selected decoder 212; thereby, facilitating increased performance.

Similarly, consider a different scenario, in which the syndrome weight indicates that decoding the data requires the decoder 212 tailored to an efficiency characteristic, involves a relatively low number of iterations during the decoding process, and/or demands a low clock frequency and/or a low voltage supply. In this example, the power management component 216 can control (e.g., provide signaling to) the clock controller 214 to decrease a frequency of the clock signals provided to the decoding component 212. Further, continuing with this example, the power management component 216 can control (e.g., provide signaling to) the switch 218 to selectively enable one of the regulators 217 (e.g., DC/DC converter) that is configured to provide a power supply of a low voltage (e.g., lower than that of a different regulator 217, such as an LDO). The decreased clock frequency, voltage, etc. can mitigate unnecessary power consumption that would occur when operating the decoder tailored reliability and/or performance characteristics.

In some embodiments, the clock frequency, the voltage, etc. can be adjusted based on one or more comparisons of the syndrome weight to one or more thresholds. For example, the clock frequency can be increased and/or the voltage regulator configured to provide a higher voltage can be selected to provide a power supply to the decoding component 212 when it is determined that the syndrome weight exceeds a threshold. In contrast, the clock frequency can be decreased and/or the voltage regulator configured to provide a lower voltage can be selected to provide a power supply to the decoding component 212 when it is determined that the syndrome weight does not exceed such threshold.

FIG. 2B illustrates another example power management system 201 in accordance with some embodiments of the present disclosure. The preliminary syndrome calculation circuitry 208, the decoding component 212, the power management component 216 illustrated in FIG. 2B can be analogous to the preliminary syndrome calculation circuitry 108, 208, the decoding component 112, 212, the power management component 116, 216 illustrated in FIGS. 1 and 2A, respectively. Further, the interface 215, the clock controller 214, and the decoders 212-1, 212-2 illustrated in FIG. 2B can be analogous to the interface 215, the clock controller 214, and the decoders 212-1, 212-2 illustrated in FIG. 2A. Although embodiments are not so limited, the power management system 201 illustrated in FIG. 2B can be an adaptive voltage and frequency scaling (AVFS) system.

The power management system 201 illustrated in FIG. 2B is generally analogous to the power management system 201 illustrated in FIG. 2A except that the voltage being provided to the decoding component 212 is adjusted by adjusting a regulated voltage provided from the voltage regulator 217. Although one voltage regulator is illustrated in FIG. 2B, embodiments are not limited to a particular quantity of voltage regulators, the power management system 210 of FIG. 2B can include.

In some embodiments, the regulator 217 can be a low dropout regulator (LDO), alternating current (AC)/direct current (DC) converter, DC/DC Buck converter, switching capacitance, etc., although embodiments are not so limited. When the voltage regulator 217 initiates supplying a regulated voltage to the decoding component 212, the regulated voltage may be at a predetermined voltage level. This predetermined voltage level can be adjusted based on the result of the preliminary syndrome calculation (e.g., a syndrome weight of the preliminary syndrome) provided from preliminary circuitry 208.

In some embodiments, the clock frequency or the voltage (e.g., from the voltage regulator 217), or both provided to the decoding component 212 can be adjusted based on one or more comparisons of the syndrome weight to one or more thresholds. For example, the clock frequency and/or the voltage can be increased when it is determined that the syndrome weight exceeds a first threshold (e.g., a high threshold). The clock frequency and/or the voltage that can be increased to allow higher performance of the decoding process can allow the timing parameters associated with operating the power management system 201 to remain as predetermined despite the high complexity of the decoding process.

Continuing with this example, the clock frequency and/or the voltage can be decreased when it is determined that the syndrome weight does not exceed a second threshold (e.g., a low threshold). If it is determined that the syndrome weight does not exceed the first threshold, but exceeds the second threshold, the clock frequency or the voltage can be maintained at a predetermined voltage level. Embodiments are not limited to a particular quantity of thresholds that can be utilized to determine whether to increase or decrease the clock frequency, the voltage, etc., and if so, by what amount.

The power management system 201 can further include a filter 219 (shown as “F” in FIG. 2B), which can smooth the signal (e.g., indicative of a respective syndrome weight) received from the preliminary circuitry 208 such that the power management component 216 receives the “smoothened” signal. For example, the filter 219 can smooth signals, ensuring that the voltage reflecting two signals consecutively received at the power management component 216 do not differ or vary by more than a specified threshold, which can further avoid the steep changes of the regulated voltage (being outputted from the voltage regulator 217).

FIG. 3 is a block diagram that illustrates an example decoding process 320 that utilizes a preliminary syndrome calculation circuitry 308 in accordance with some embodiments of the present disclosure. The device 309, the decoding circuitries 312-1, 312-2, the preliminary syndrome calculation circuitry 308, and the interface 315 illustrated in FIG. 3 can be analogous to the device 109, the decoding circuitries 212-1, 212-2, the preliminary syndrome calculation circuitry 108, 208, and the interface 215 illustrated in FIGS. 1-2, respectively. However, embodiments are not limited to a particular quantity of decoders 312 that can be utilized for the decoding process 320.

Although embodiments are not so limited, the decoder 312-1 coupled between the preliminary syndrome calculation circuitry 308 and the decoder 312-2 can correspond to the decoder tailored to an efficiency characteristic, while the decoder 312-2 can correspond to the decoder tailored to a reliability characteristic. The decoder 312-1 that is tailored to an efficiency characteristic may utilize less resources than the decoder 312-2 tailored to a reliability characteristic, while the decoder 312-2 may be capable of correcting errors on the bit strings with a BER exceeding the capability of the decoder 312-1.

Although embodiments are not so limited, the decoder 312-1 can be/include a bit-flipping decoder, while the decoder 312-2 can be/include a MIN-SUM decoder. As used herein, the term “bit flipping decoder” refers to a decoder that utilizes a simple iterative algorithm (e.g., utilized in error-correcting codes like LDPC and binary linear block codes), which iteratively corrects received codewords by flipping individual bits violating parity constraints until convergence or a maximum iteration limit is reached. Further, as used herein, the term “MIN-SUM decoder” refers to a decoder that utilizes iterative message-passing algorithm (e.g., used in error-correcting codes such as LDPC and turbo codes), which aims to minimize the sum of log-likelihood ratios associated with each bit to determine the most likely transmitted codeword in the presence of noise.

Although not illustrated in details in FIG. 3, the decoder 312 can include various circuitry to perform the operations (e.g., syndrome calculations, decoding operations, etc.), such as arrays of memory cells, various logic gates (AND gates, OR gates, NOT gates, NAND gates, NOR gates, XOR gates, etc.), multiplexer (MUX)/de-MUX gates, shifting circuitry, decision engines, although embodiments are not so limited. The decision engines of the decoders can flip one or more bits of codewords (alternatively referred to as “bit strings”) and/or syndrome based on a determined probability that such bits are erroneous. As used herein, the term “codeword” generally refers to a data word having a specified size (e.g., 4 KB, etc.) that is encoded such that the codeword can be individually protected by some error encoding and/or decoding scheme. For example, a “codeword” can refer to a set of bits (e.g., a bit string) that can be individually encoded and/or decoded.

The probability that one or more bits are erroneous can be determined using various linear codes, such as syndrome decoding codes, LDPC codes, etc. Embodiments are not limited to cases in which the decoder 312 corrects the errors based on a determined probability that such bits are erroneous (e.g., through the use of a linear decoding technique), however, and in some embodiments, the decoder 312 can determine which bits of the bit strings and/or syndromes are erroneous based on mathematical inference algorithms, machine learning algorithms, and/or other suitable techniques for determining which bits of the bit strings and/or syndromes are erroneous.

While error correction techniques described in association with FIGS. 1-6 are exemplified by “syndrome calculation”, it is crucial to note that the error correction technique utilizing syndromes and described herein is merely an example representation of codeword errors. Different error correction algorithms, such as, but not limited to, parity, error signature, CRC sum, and others, may also be utilized for the decoding process 320. Alternatively speaking, a preliminary “error assessment” and/or further error correction and/or decoding operations that may be performed at the decoders 312 are not limited to a syndrome calculation, but may include other various error correction techniques, such as, but not limited to, parity, error signature, CRC sum, and others and without being constrained by specific error correction algorithms.

The decoders 312 can include shift circuitry that can be further used during the syndrome calculations and/or decoding operations. As used herein, the term “syndrome calculation” refers to one or more operations that calculates (e.g., generates) a syndrome and/or correct one or more bits of the calculated syndrome, while the term “decoding operation” refers to an operation that attempts to correct one or more bit errors based on the calculated syndromes. The syndrome calculated at the decoders 312 (and/or preliminary syndrome calculation circuitry 308) can reflect a current error state associated with data contained within the bit string (e.g., codeword). For example, the value of the syndromes (e.g., calculated at the preliminary syndrome calculation circuitry 308) being zero implies that the bit string has no errors and thus has been successfully decoded. However, each bit of the syndromes having a particular logical value (e.g., “1”) can make the value of the syndromes non-zero; thereby, indicating that the bit string has errors. As used herein, a quantity of bits having the particular logical value, such as “1”, of the syndrome can be referred to as “syndrome weight” (alternatively referred to as “a quantity of parity violations”).

Alternatively speaking, various operations performed at the decoders 312 make reference to both bit strings and/or syndromes in order to illustrate various aspects of the present disclosure. In some embodiments, when one or more bits of a bit string are corrected, a corresponding syndrome can be updated to reflect a current error state of the syndrome.

Although embodiments are not so limited, the syndrome calculations and/or decoding operations performed at the decoders 312 can be iterative. For example, one or more erroneous bit of a bit string identified and/or a “non-zero” syndrome calculated as a result of the first iteration of the syndrome calculation and/or decoding operation may be corrected during a second iteration of the syndrome calculation and/or decoding operation, and one or more remaining erroneous bit of the bit string identified and/or a “non-zero” syndrome calculated as a result of the second iteration of the syndrome calculation may be corrected during a third iteration of the syndrome calculation and/or decoding operation.

Decoding of bit strings and/or syndromes at the decoders 312 can be achieved by shifting the bit strings and/or syndromes using shift circuitry, which one or more barrel shifters. The barrel shifters are configured to shift (e.g., cyclically shifting, which is alternatively referred to as “circular shifting”) the bit strings and/or syndromes by a specified number of bits, for example, using pure combinatorial logic. Embodiments are not so limited, however, and it is contemplated within the disclosure that the shift circuitry can be configured to perform shift operations involving the bit strings and/or syndromes utilizing other combinatorial logic techniques (e.g., circular shifting, etc.) and/or sequential logic techniques.

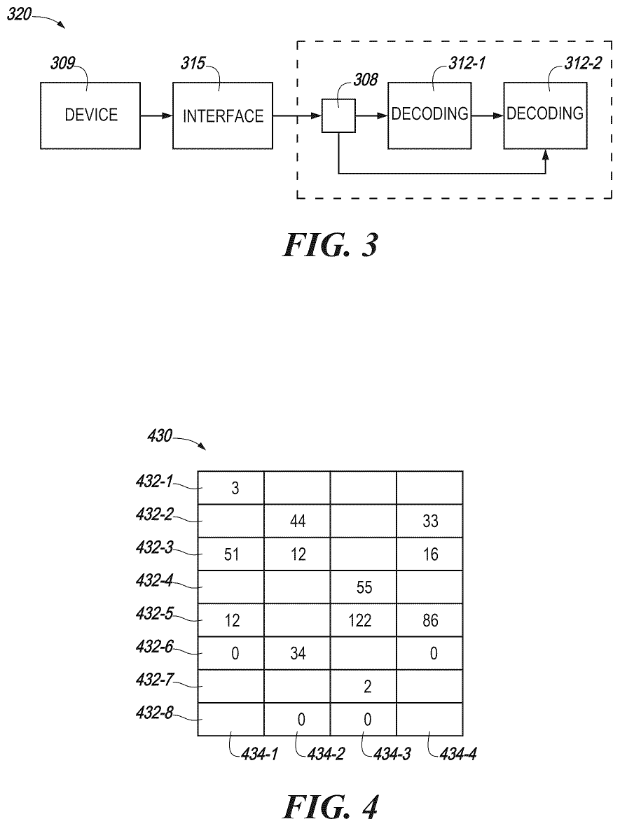

In some embodiments, the bit strings and/or syndromes that are processed (e.g., subjected to the operations described above as part of decoding the bit strings and/or syndromes) are determined by values in columns of a parity-check matrix (e.g., an H matrix, such as an H matrix 430 illustrated in FIG. 4) and the quantity of bits by which the barrel shifters shift the bits of the bit strings and/or syndromes are generally determined based on values indicated by bit patterns aligned in a particular orientation (e.g., the bit patterns respectively corresponding to rows, which can be grouped into “layers”, such as layers 432 illustrated in FIG. 4) of the parity-check matrix. For example, which bit strings and/or syndromes to decode are selected (e.g., blocks of parity checks) based on corresponding values in the columns of the parity-check matrix and an offset by which to cyclically shift the bit strings and/or syndromes by the one or more barrel shifters is selected based on corresponding values in the rows of the parity-check matrix. As used herein, rows and columns of a parity-check matrix can be referred to as bit patterns aligned in respective orientation. For example, a row can be referred to as a bit pattern aligned in a first orientation and a column can be referred to as a bit pattern aligned in a second orientation, or vice versa.

The preliminary syndrome calculation circuitry 308 is located close to the interface 315 in a manner that a codeword transferred via the interface 315 is received to the preliminary syndrome calculation circuitry 308 prior to the decoders 312. Alternatively, although the preliminary syndrome calculation circuitry 308 is illustrated as being separate from the interface 315, the preliminary syndrome calculation circuitry 308 can be also part of the interface 315 and/or the device 309 in some embodiments. For example, the preliminary syndrome calculation circuitry 308 can be resident on the interface 315. The close coupling or the fact that the preliminary syndrome calculation circuitry 308 is part of the interface 315 allows a preliminary syndrome to be available at the early stage of the codeword processing (e.g., accessing codewords from the device 109 illustrated in FIG. 1 and/or decoding the codewords at the decoders 312). This further allows sufficient time for the clock controller 214 and/or the voltage regulators 217 illustrated in FIGS. 2A-2B to react as instructed by the power management component 216.

The preliminary syndrome calculation circuitry 308 can perform a syndrome calculation (based on the codeword received from the interface 315) and/or decoding operations partially on the bit strings received from the interface 315. Although embodiments are not so limited, the preliminary syndrome calculation can be performed by accessing a codeword store in a buffer of the interface 315.

The syndrome calculation performed at the preliminary syndrome calculation circuitry 308 can be “on the fly” and a simplified version of the syndrome calculation performed at the decoders 312-1, 312-2. For example, the preliminary syndrome calculation circuitry 308 can perform a syndrome calculation using merely a portion of the parity-check matrix (e.g., the sparse parity-check matrix 440 illustrated in FIG. 4), such as one “layer” (e.g., the layer 432-8 illustrated in FIG. 4) among layers of the parity-check matrix. Accordingly, such syndrome calculation can involve merely a portion of the codeword that corresponds only to the portion of the parity-check matrix. As used herein, a syndrome calculated at the preliminary syndrome calculation circuitry 308 can be referred to as “preliminary syndrome”. This particular layer (corresponding to a portion of the codeword) may demonstrate a strong correlation between its syndrome weight and the overall BER of the entire codeword. Consequently, this correlation enables the use of syndrome weight of this particular layer as a means to estimate the BER and/or perform various operations as if they were performed based on the estimated BER.

In a number of embodiments, such layer used for the syndrome calculation at the preliminary syndrome calculation circuitry 308 can be a layer that does not require barrel shifters. Alternatively speaking, a shifting indicator (e.g., how many bits of the portion of the codeword and/or syndrome will be shifted for the syndrome calculation) corresponding to such a layer is zero such that the syndrome calculation can be performed without shifting bits of the portion of the codeword and/or syndrome. Further details of layers and the parity-check matrix is described in connection with FIG. 4.

Although embodiments are not so limited, the syndrome calculation performed at the preliminary syndrome calculation circuitry 308 can be iterative. For example, one or more erroneous bit of a “non-zero” syndrome calculated as a result of the first iteration of the syndrome calculation may be corrected during a second iteration of the syndrome calculation, and one or more remaining erroneous bit of a “non-zero” syndrome calculated as a result of the second iteration of the syndrome calculation may be corrected during a third iteration of the syndrome calculation.

The preliminary syndrome calculation circuitry 308 can further determine where to route the codeword based on the determined syndrome weight. For example, if the determined syndrome weight exceeds the threshold (which indicates that the syndrome may not be successfully decoded at the decoder 312-1), the syndrome can be routed to the decoder 312-2 directly (e.g., by bypassing the decoder 312-1). For example, if the determined syndrome weight does not exceed the threshold (which indicates that the syndrome may be successfully decoded at the decoder 312-1), the calculated syndrome can be routed to the decoder 312-1. The determination involving the routing can be performed by a decision component of the preliminary syndrome calculation circuitry 308 that can be implemented in forms of hardware, firmware, or any combination thereof.

This routing scheme can potentially avoid the situation where the codeword is unnecessarily routed to the decoder 312-1 when errors need to be corrected at the decoder 312-2 anyhow due to the high BER of the codeword exceeding the capability of the decoder 312-1. Still, the decoder 312-1 may also be configured to route the calculated syndrome to the decoder 312-2 in the event that the syndrome received from the preliminary syndrome calculation circuitry 308 was not successfully decoded at the decoder 312-1. Otherwise (if the syndrome was successfully decoded at the decoder 312-1), the syndrome may not be routed to the decoder 312-2.

If the syndrome weight determined by the preliminary syndrome calculation circuitry 308 exceeds another threshold, which is beyond the decoding capability of any one of the decoders 312 (e.g., even the decoder 312-2 tailored to a reliability characteristic), the preliminary syndrome calculation circuitry 308 and/or the controller 105 illustrated in FIG. 1 may not initiate the decoding process at the decoders 312. For example, the codeword that has been stored in the buffer may not be transferred to the decoders 312. Rather, in some embodiments, the preliminary syndrome calculation circuitry 308 and/or the controller 105 can request the device 309 to re-transfer the codeword, which can be written again to the buffer where the preliminary syndrome calculation can be performed again. Accordingly, in the event that the codeword is to be re-transferred from the device 309 to the interface 315 in the above-mentioned scenario, the latencies associated with decoding the codeword can be substantially reduced compared to those approaches where a “full” syndrome calculation (e.g., at the decoders, such as bit-flip decoder, MIN-SUM decoder, etc.) was required to have been performed prior to determining that the re-transfer of the codeword is necessary. In some embodiments, in which a syndrome resulted from the syndrome calculation performed at the preliminary syndrome calculation circuitry 308 corresponds to a “full” syndrome (as opposed to “partial” syndrome calculated only a portion of the matrix 430 illustrated in FIG. 4), the corresponding codeword may not be routed to any one of the decoders 312-1 or 312-2 if the full syndrome calculated at the preliminary syndrome calculation circuitry 308 is determined to be a zero syndrome (e.g., syndrome weight is zero). Alternatively speaking, the codeword may instead be read (e.g., to the host 102 illustrated in FIG. 1) without triggering operation of the decoders 312-1 and 312-2 in such event.

FIG. 4 illustrates an example sparse parity-check matrix 440 in accordance with some embodiments of the present disclosure. The sparse parity-check matrix can be referred to as an “H-matrix” in accordance with parlance common in the art and can be used to specify an error correction code, such as a low-density parity check code. Further, although embodiments are not so limited, the parity-check matrix 440 illustrated in FIG. 4 can be of a quasi-cyclic LDPC code. The sparse parity-check matrix 440 can be stored in the preliminary syndrome calculation circuitry 108, 208, 308 and/or the decoding component 112, 212 illustrated in FIGS. 1-3, respectively. Alternatively the sparse-parity-check matrix 440 can be stored in a memory separate from the preliminary syndrome calculation circuitry 108, 208, 308 and/or the decoding component 112, 212.

The sparse parity-check matrix can include layers, such as layer 432-1, . . . , 432-8 illustrated in FIG. 4. The sparse parity-check matrix 440 may not be illustrated in its entirety in FIG. 4. Accordingly, the sparse parity-check matrix 440 can include more or less than 8 layers. Further, each layer 432 can include a number of “entries”, which can be defined by intersections of 432 (432-1, . . . , 432-8) and 434 (434-1, . . . , 434-4). For example, as illustrated in FIG. 4, the layer 432-8 includes 4 entries which are respectively located at intersections of 432-8 and 434-1, 432-8 and 434-2, 432-8 and 434-3, and 432-8 and 434-4. Embodiments are not limited to a particular orientation of a parity-check matrix, in which bit patterns (corresponding to rows and/or columns) can be aligned. For example, while FIG. 4 illustrates layers 432-1, . . . , 432-8 of the parity-check matrix 440 aligned in an orientation corresponding to “row”, the layers 432-1, . . . , 432-8 can also be aligned in a different orientation corresponding to “column”.

Although not illustrated in FIG. 4 in detail, each layer consists of a particular quantity of rows, such as one hundred twenty-eight (128) rows, although embodiments are not limited to this particular enumerated quantity of rows. The quantity of rows corresponding to each layer can be referred to as the circulant size for the sparse-parity-check matrix 440.

As an example, the layer 432-1 of the sparse-parity-check matrix 440 can include a quantity of rows, such as one hundred twenty-eight (128) rows; the layer 432-2 of the sparse-parity-check matrix 440 can include another quantity of rows, such as another hundred twenty-eight (128) rows; the layer 432-3 of the sparse-parity-check matrix 440 can include another quantity of rows, such as another hundred twenty-eight (128) rows; the layer 432-4 of the sparse-parity-check matrix 440 can include another quantity of rows, such as another hundred twenty-eight (128) rows; the layer 432-5 of the sparse-parity-check matrix 440 can include another quantity of rows, such as another hundred twenty-eight (128) rows; the layer 432-6 of the sparse-parity-check matrix 440 can include another quantity of rows, such as another hundred twenty-eight (128) rows; the layer 432-7 of the sparse-parity-check matrix 440 can include another quantity of rows, such as another hundred twenty-eight (128) rows; and the layer 432-8 of the sparse-parity-check matrix 440 can include another quantity of rows, such as another hundred twenty-eight (128) rows.

Each layer can also include a quantity of columns and each column can correspond to a respective bit of the codeword. For example, if the codeword includes 37,000 bits, each layer can include 37,000 columns (with each column having a number of binary values, such as “0” or “1”). Further, each entry of the layer can include a particular quantity of columns, such as 128 columns, although embodiments are not so limited. Therefore, in this particular example, a syndrome calculation for each entry having 128 columns involves performing XOR operations utilizing 128 bits of the codeword.

As shown in FIG. 4, the sparse parity-check matrix 440 includes numerical values. For example, the layer 432-1 includes a numerical value of “3” at an entry located at 434-1; the layer 432-2 includes numerical values of “44” and “33” at entries respectively located at 434-2 and 434-4; the layer 432-3 includes numerical values of “51”, “12”, and “16” at entries respectively located at 434-1, 434-2, and 434-4; the layer 432-4 includes numerical values of “55” at an entry located at 434-3; the layer 432-5 includes numerical values of “12”, “122”, and “86” at entries respectively located at 434-1, 434-3, and 434-4; the layer 432-6 includes numerical values of “0”, “34”, and “0” at entries respectively located at 434-1, 434-2, and 434-4; the layer 432-7 includes numerical values of “2” at an entry located at 434-3; and the layer 432-8 includes numerical values of “0” and “0” at entries respectively located at 434-2 and 434-3.

Each numerical value is indicative of a quantity of bits by which the corresponding syndrome is to be shifted (e.g., using one or more barrel shifters) during syndrome calculations and/or decoding operations performed at the decoding circuitry 312-1 and/or decoding circuitry 312-2. For example, the syndrome calculation and/or decoding operations performed utilizing the layer 432-1 involves shifting the corresponding bit string and/or syndrome by “3”. Further, for example, the syndrome calculations and/or decoding operations performed utilizing the layer 432-5 involves shifting the corresponding bit string and/or syndrome (e.g., corresponding to the entry located at 434-1 of the layer 432-5) by “12”, shifting the corresponding bit string and/or syndrome (e.g., corresponding to the entry located at 434-3 of the layer 432-5) by “122”, and shifting the corresponding bit string and/or syndrome (e.g., corresponding to the entry located at 434-4 of the layer 432-5) by “86”.

Syndrome calculations performed at the preliminary syndrome calculation circuitry 308 can be performed using a portion of the layers, such as the 432-8 (e.g., a last layer) only. Syndrome calculations and/or decoding operations performed utilizing the layer 432-8 do not involve shifting bits of the corresponding bit string and/or syndromes as the numerical values of the layer 432-8 are “0”. While embodiments are not so limited, selecting this layer for the preliminary syndrome calculation (performed at the preliminary syndrome calculation circuitry 308) can eliminate a need to have shifting circuitry (e.g., barrel shifters) at the preliminary syndrome calculation circuitry 108, 208, 308s; thereby, reducing the latencies associated with calculating syndromes.

Syndrome calculations can be selectively performed depending on whether a respective entry of each layer 432 includes a numerical value or not. For example, when performing syndrome calculations utilizing the layer 432-2, the syndrome calculations can be selectively performed utilizing portions of the codeword corresponding to one entry having “44” (and located at 434-2 of the layer 432-2) and another entry having “33” (and located at 434-4 of the layer 432-2), while syndrome calculations that would have been performed utilizing portions of the codeword corresponding to entries respectively located at 434-1 and 434-3 may not be performed.

In some embodiments, a syndrome calculation (e.g., preliminary syndrome calculation) utilizing the layer 432-8 can include multiplying a first portion (e.g., a quantity of bits, such as 128 bits, corresponding to an “entry” and alternatively referred to as “relevant part”) of the codeword by columns of the entry located at 434-2 of the layer 432-8 and a second portion (e.g., a quantity of bits, such as 128 bits, corresponding to an “entry”) of the codeword by rows of the entry located at 434-3 of the layer 432-8. Although embodiments are not so limited, the multiplication of the respective portion by the parity-check matrix 440 (e.g., a respective entry of the parity-check matrix 440) can include XORing each bit of the portion (e.g., 128 bits) with each bit of a respective row (e.g., having 128 bits respectively on 128 columns) of the entry. In some embodiments, a quantity of bits of the codeword (e.g., 256 bits, although embodiments are not so limited) corresponding to two entries located at 434-1 and 434-4 of the layer 432-8 may not be utilized in calculating the syndromes. In sum, an equation corresponding to a syndrome calculation can be expressed as follows:

$$s = {\sum }_{i = 0}^{127} {⊕}_{j = 0}^{r - 1} w ( {L}_{j} * 128 + i )$$

where “S” is a syndrome weight, “W” is a word (e.g., codeword), “i” is a row index, which can range from “0” to “127” (e.g., 128 iterations as defined by the circulant size), and “r” is a row weight indicating a number of non-empty entries in the row. Further, “Lj” is the index of the j-th non-empty column in the layer with “j” ranging from “0”. For example, the “Lj” on the layer 432-1 starts from the index “0” (corresponding to a column 434-1), while the “Lj” on the layer 432-2 starts from the index “1” (corresponding to a column 434-2).

In a number of embodiments, a syndrome weight calculated from the layer 432-8 demonstrates a strong correlation with the BER of the codeword. This correlation enables the preliminary syndrome to serve as a primary factor in deciding the routing destination for the codeword (e.g., to the decoding circuitry 312-1 or the decoding circuitry 312-2 illustrated in FIG. 3). This aims to mitigate the possibility of inaccurately estimating the codeword's BER, which could otherwise lead to suboptimal routing decisions, and undesirably and increased decoding latencies at the decoding circuitries 312. While the layer 432-8 can be a “last” layer as shown in FIG. 4 (e.g., located at the bottom of the parity-check matrix 440), the parity-check matrix 440 can be designed in a manner that embodiments are not limited to a geometrical location of this layer (e.g., the layer 432-8) utilized by the preliminary syndrome calculation circuitry 108, 308 within the parity-check matrix 440.

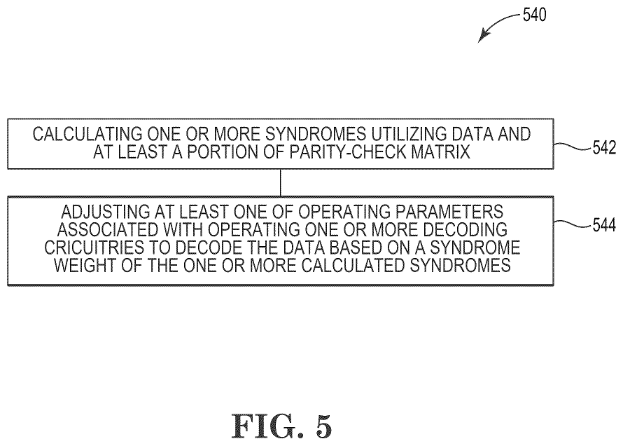

FIG. 5 is a flow diagram corresponding to a method 540 for power adjustment based on preliminary syndrome calculation in accordance with some embodiments of the present disclosure. The method 540 can be performed by processing logic that can include hardware (e.g., processing device, circuitry, dedicated logic, programmable logic, microcode, hardware of a device, integrated circuit, etc.), software (e.g., instructions run or executed on a processing device), or a combination thereof. In some embodiments, the method 540 is performed by the syndrome calculation circuitry 108, 208, 308 (e.g., the controller 105 of FIG. 1) and/or the power management component 116, 216 of FIGS. 1-3. Although shown in a particular sequence or order, unless otherwise specified, the order of the processes can be modified. Thus, the illustrated embodiments should be understood only as examples, and the illustrated processes can be performed in a different order, and some processes can be performed in parallel. Additionally, one or more processes can be omitted in various embodiments. Thus, not all processes are required in every embodiment. Other process flows are possible.

At operation 542, the method 540 includes calculating one or more syndromes (e.g., at the preliminary circuitry 108, 208, 308 illustrated in FIGS. 1-3 herein) utilizing data (e.g., corresponding to a codeword) and at least a portion (e.g., the layer 342-8 illustrated in FIG. 4 herein) of parity-check matrix (e.g., the parity-check matrix 440 illustrated in FIG. 4 herein). At operation 544, the method 540 further includes adjusting at least one of operating parameters associated with operating one or more decoding circuitries (e.g., the decoding circuitry 212, 312 illustrated in FIGS. 1-3 herein) to decode the data based on a syndrome weight of the one or more calculated syndromes. As used herein, those resources and/or parameters (e.g., a voltage provided from the regulators 217-1, 217-2 illustrated in FIGS. 2A-2B herein or a clock frequency) can generally be referred to as “operating parameters”, which in turn refers to parameters that can be controlled and/or adjusted to regulate the operation of a system (e.g., the electronic system 100 illustrated in FIG. 1). However, while the operating parameters are exemplified by the control of the clock frequency, the voltage, or any combination thereof, embodiments of the present disclosure are not limited to such. For example, the scope of the invention is also applicable to the management and adjustment of any resource. For example, the operating parameters can include, but not limited to, the control of the number of decision engines (that may be implemented within the preliminary circuitry 108, 208, 308 illustrated in FIGS. 1-3 herein) actively handling the routing process, prioritization of processes, allocation of power resources, adjustment of power supply currents, and regulation of cooling aids.

In some embodiments, the clock frequency, the voltage, or any combination thereof, can be increased responsive to determining that a syndrome weight of the one or more syndromes exceeds a first threshold syndrome weight. In some embodiments, the clock frequency, the voltage, or any combination thereof, can be decreased responsive to determining that a syndrome weight of the one or more syndromes does not exceed a first threshold syndrome weight.

In some embodiments, one voltage regulator among a plurality of voltage regulators (e.g., the regulators 217-1, 217-2 illustrated in FIG. 2A herein) can be selectively enabled and operated to adjust the voltage associated with operating the one or more decoding circuitries 212, 312 based on the calculated syndrome weight. In some embodiments, a regulated voltage of a voltage regulator (e.g., the regulators 217 illustrated in FIG. 2B herein) can be adjusted to adjust the voltage associated with operating the one or more decoding circuitries 212, 312 based on the calculated syndrome weight. Continuing with this example, the regulated voltage can be prevented from being adjusted by more than a threshold amount, while adjusting the voltage of the voltage regulator 217.

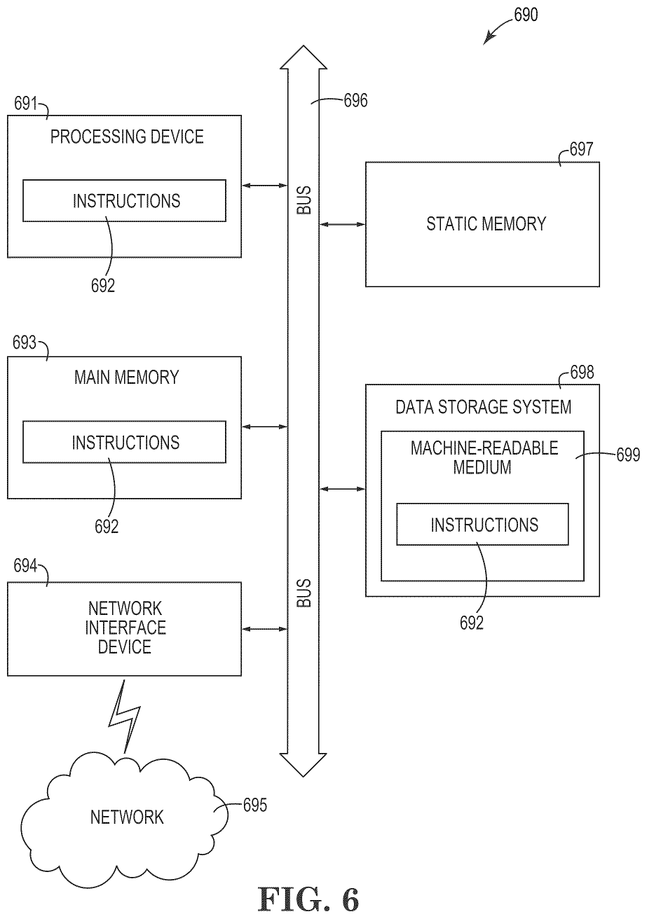

FIG. 6 is a block diagram of an example computer system in which embodiments of the present disclosure may operate. For example, FIG. 6 illustrates an example machine of a computer system 690 within which a set of instructions, for causing the machine to perform any one or more of the methodologies discussed herein, can be executed. In some embodiments, the computer system 690 can correspond to a host system (e.g., the host system 102 of FIG. 1) that includes, is coupled to, or utilizes a controller and/or a device (e.g., the controller 105 and/or the device 109 of FIG. 1) or can be used to perform the operations of a controller (e.g., to execute an operating system to perform operations corresponding to the power management component 116, 216 of FIGS. 1-2). In alternative embodiments, the machine can be connected (e.g., networked) to other machines in a LAN, an intranet, an extranet, and/or the Internet. The machine can operate in the capacity of a server or a client machine in client-server network environment, as a peer machine in a peer-to-peer (or distributed) network environment, or as a server or a client machine in a cloud computing infrastructure or environment.

The machine can be a personal computer (PC), a tablet PC, a set-top box (STB), a Personal Digital Assistant (PDA), a cellular telephone, a web appliance, a server, a network router, a switch or bridge, or any machine capable of executing a set of instructions (sequential or otherwise) that specify actions to be taken by that machine. Further, while a single machine is illustrated, the term “machine” shall also be taken to include any collection of machines that individually or jointly execute a set (or multiple sets) of instructions to perform any one or more of the methodologies discussed herein.

The example computer system 690 includes a processing device 691, a main memory 693 (e.g., read-only memory (ROM), flash memory, dynamic random access memory (DRAM) such as synchronous DRAM (SDRAM) or Rambus DRAM (RDRAM), etc.), a static memory 697 (e.g., flash memory, static random access memory (SRAM), etc.), and a data storage system 698, which communicate with each other via a bus 696.

The processing device 691 represents one or more general-purpose processing devices such as a microprocessor, a central processing unit, or the like. More particularly, the processing device can be a complex instruction set computing (CISC) microprocessor, reduced instruction set computing (RISC) microprocessor, very long instruction word (VLIW) microprocessor, or a processor implementing other instruction sets, or processors implementing a combination of instruction sets. The processing device 691 can also be one or more special-purpose processing devices such as an application specific integrated circuit (ASIC), a field programmable gate array (FPGA), a digital signal processor (DSP), network processor, or the like. The processing device 691 is configured to execute instructions 692 for performing the operations and steps discussed herein. The computer system 690 can further include a network interface device 694 to communicate over the network 695.

The data storage system 698 can include a machine-readable storage medium 699 (also known as a computer-readable medium) on which is stored one or more sets of instructions 692 or software embodying any one or more of the methodologies or functions described herein. The instructions 692 can also reside, completely or at least partially, within the main memory 693 and/or within the processing device 691 during execution thereof by the computer system 690, the main memory 693 and the processing device 691 also constituting machine-readable storage media. The machine-readable storage medium 699, data storage system 698, and/or main memory 693 can correspond to the memory sub-system 103 of FIG. 1.

In one embodiment, the instructions 692 include instructions to implement functionality of the power management component (e.g., the power management component 116, 216 of FIG. 1-2) 108, 208. While the machine-readable storage medium 699 is shown in an example embodiment to be a single medium, the term “machine-readable storage medium” should be taken to include a single medium or multiple media that store the one or more sets of instructions. The term “machine-readable storage medium” shall also be taken to include any medium that is capable of storing or encoding a set of instructions for execution by the machine and that cause the machine to perform any one or more of the methodologies of the present disclosure. The term “machine-readable storage medium” shall accordingly be taken to include, but not be limited to, solid-state memories, optical media, and magnetic media.

Some portions of the preceding detailed descriptions have been presented in terms of algorithms and symbolic representations of operations on data bits within a computer memory. These algorithmic descriptions and representations are the ways used by those skilled in the data processing arts to most effectively convey the substance of their work to others skilled in the art. An algorithm is here, and generally, conceived to be a self-consistent sequence of operations leading to a desired result. The operations are those requiring physical manipulations of physical quantities. Usually, though not necessarily, these quantities take the form of electrical or magnetic signals capable of being stored, combined, compared, and otherwise manipulated. It has proven convenient at times, principally for reasons of common usage, to refer to these signals as bits, values, elements, symbols, characters, terms, numbers, or the like.

It should be borne in mind, however, that all of these and similar terms are to be associated with the appropriate physical quantities and are merely convenient labels applied to these quantities. The present disclosure can refer to the action and processes of a computer system, or similar electronic computing device, that manipulates and transforms data represented as physical (electronic) quantities within the computer system's registers and memories into other data similarly represented as physical quantities within the computer system memories or registers or other such information storage systems.

The present disclosure also relates to an apparatus for performing the operations herein. This apparatus can be specially constructed for the intended purposes, or it can include a general purpose computer selectively activated or reconfigured by a computer program stored in the computer. Such a computer program can be stored in a computer readable storage medium, such as, but not limited to, any type of disk including floppy disks, optical disks, CD-ROMs, and magnetic-optical disks, read-only memories (ROMs), random access memories (RAMs), EPROMs, EEPROMs, magnetic or optical cards, or any type of media suitable for storing electronic instructions, each coupled to a computer system bus.

The algorithms and displays presented herein are not inherently related to any particular computer or other apparatus. Various general purpose systems can be used with programs in accordance with the teachings herein, or it can prove convenient to construct a more specialized apparatus to perform the method. The structure for a variety of these systems will appear as set forth in the description below. In addition, the present disclosure is not described with reference to any particular programming language. It will be appreciated that a variety of programming languages can be used to implement the teachings of the disclosure as described herein.

The present disclosure can be provided as a computer program product, or software, that can include a machine-readable medium having stored thereon instructions, which can be used to program a computer system (or other electronic devices) to perform a process according to the present disclosure. A machine-readable medium includes any mechanism for storing information in a form readable by a machine (e.g., a computer). In some embodiments, a machine-readable (e.g., computer-readable) medium includes a machine (e.g., a computer) readable storage medium such as a read only memory (“ROM”), random access memory (“RAM”), magnetic disk storage media, optical storage media, flash memory devices, etc.

In the foregoing specification, embodiments of the disclosure have been described with reference to specific example embodiments thereof. It will be evident that various modifications can be made thereto without departing from the broader spirit and scope of embodiments of the disclosure as set forth in the following claims. The specification and drawings are, accordingly, to be regarded in an illustrative sense rather than a restrictive sense.

What is claimed is:

1. A method, comprising:
calculating one or more syndromes utilizing data and parity-check matrix; and
adjusting at least one of operating parameters associated with operating one or more decoding circuitries to decode the data based on a syndrome weight of the one or more calculated syndromes, the syndrome weight corresponding to a bit error rate (BER) of the data.

2. The method of claim 1, wherein the operating parameters include a voltage, a clock frequency, or any combination thereof.

3. The method of claim 2, further comprising:
increasing the clock frequency, the voltage, or any combination thereof responsive to determining that a syndrome weight of the one or more syndromes exceeds a first threshold syndrome weight; and
decreasing the clock frequency, the voltage, or any combination thereof responsive to determining that a syndrome weight of the one or more syndromes does not exceed a first threshold syndrome weight.

4. The method of claim 2, further comprising selectively operating one voltage regulator among a plurality of voltage regulators to adjust the voltage associated with operating the one or more decoding circuitries based on the calculated syndrome weight.

5. The method of claim 2, further comprising adjusting a regulated voltage of a voltage regulator to adjust the voltage associated with operating the one or more decoding circuitries based on the calculated syndrome weight.

6. The method of claim 5, further comprising, while adjusting the voltage of the voltage regulator:
preventing the regulated voltage from being adjusted by more than a threshold amount.

7. An apparatus, comprising:
preliminary syndrome calculation circuitry configured to calculate a syndrome utilizing data and a portion of a parity-check matrix; and
a power management component configured to control a clock controller or a voltage regulator, or both, to respectively adjust a clock frequency, a voltage, or both, associated with operating a decoding component to decode the data based on a syndrome weight of the syndrome calculated at the preliminary syndrome calculation circuitry.

8. The apparatus of claim 7, wherein:
the voltage regulator is one of a plurality of voltage regulators coupled to switching circuitry; and
the power management component is configured to control switching circuitry to selectively allow, while the other voltage regulators are prevented from providing respective powers, one of the plurality of voltage regulators to provide a power based on the syndrome weight of the syndrome calculated at the preliminary syndrome calculation circuitry.

9. The apparatus of claim 7, wherein the power management component is configured to provide one or more signals to the voltage regulator to cause the voltage regulator to increase or decrease the voltage of the voltage regulator.

10. The apparatus of claim 9, wherein:
a filter is coupled between the preliminary syndrome calculation circuitry and the power management; and
the filter is configured to smooth the one or more signals to prevent voltages indicative of corresponding to two signals consecutively received at the power management component from varying by more than a threshold amount.

11. The apparatus of claim 7, wherein:
the decoding component comprises a plurality of decoding circuitries respectively configured to decode data; and
wherein the syndrome weight of the syndrome is indicative of which decoding circuitry among the plurality of decoding circuitries is to decode the data.

12. A apparatus, comprising:
a power management component; and
preliminary syndrome calculation circuitry configured to:
calculate a syndrome utilizing:
a portion of data corresponding to a codeword; and
a portion of a plurality of sets of bit patterns aligned in a first orientation in a parity-check matrix;
determine a syndrome weight of the calculated syndrome; and
provide a signal indicative of the syndrome weight to the power management component;
wherein the power management component is configured to control a clock controller or a voltage regulator, or both, to respectively adjust a clock frequency, a voltage, or both, associated decoding the data based on the syndrome weight of the syndrome.

13. The apparatus of claim 12, wherein the power management component is configured to:
control the clock controller or the voltage regulator, or both, to respectively increase the clock frequency, the voltage, or both, in response to the syndrome weight exceeding a first threshold; and
control the clock controller or the voltage regulator, or both, to respectively decrease the clock frequency, the voltage, or both, in response to the syndrome weight not exceeding the first threshold.

14. The apparatus of claim 12, wherein the power management component is configured to:
control the clock controller or the voltage regulator, or both, to respectively increase the clock frequency, the voltage, or both, in response to the syndrome weight exceeding a first threshold; and
control the clock controller or the voltage regulator, or both, to respectively decrease the clock frequency, the voltage, or both, in response to the syndrome weight not exceeding a second threshold.

15. The apparatus of claim 14, wherein the power management component is configured to control the voltage regulator to maintain the voltage of the voltage regulator at a predetermined voltage level.

16. The apparatus of claim 12, further comprising a plurality of decoding circuitries having:
a first decoding circuitry; and
a second decoding circuitry, wherein the second decoding circuitry is capable of correcting errors on data having a higher bit error rate (BER) than the first decoding circuitry is capable of.

17. The apparatus of claim 16, wherein the power management component is configured to control the clock controller or the voltage regulator, or both, to respectively increase the clock frequency, the voltage, or both, in response to the syndrome weight indicating the data to be decoded at the second decoding circuitry.

18. The apparatus of claim 16, wherein the power management component is configured to control the clock controller or the voltage regulator, or both, to respectively decrease the clock frequency, the voltage, or both, in response to the syndrome weight indicating the data to be decoded at the first decoding circuitry.

19. The apparatus of claim 12, wherein:
each set of the plurality of sets of bit patterns corresponds to a respective layer of a plurality of layers; and
wherein each layer of the plurality of layers further stores one or more numerical values indicative of a quantity of bits by which the codeword or a corresponding syndrome is to shift.

20. The apparatus of claim 19, wherein the portion of the plurality of sets of bit patterns corresponds to a particular layer storing one or more numerical values of zero.
